(19) United States
(12) Patent Application Publication
(10) Pub. No.: US 2011/0048537 A1
(43) Pub. Date: Mar. 3, 2011

(54) METHOD OF FABRICATING A SEMICONDUCTOR JUNCTION

(76) Inventors: Jerry M. Woodall, West Point, IN (US); Kyle H. Montgomery, Lafayette, IN (US)

(21) Appl. No.: 12/827,390

(22) Filed: Jun. 30, 2010

Related U.S. Application Data
(60) Provisional application No. 61/238,310, filed on Aug. 31, 2009.

(51) Int. Cl. H01L 31/0296; H01L 21/20; H01L 29/24

(52) U.S. Cl. 136/262; 438/478; 257/103; 257/E21.09; 257/E31.015; 257/E29.1

(57) ABSTRACT

A method of fabricating a semiconductor junction is disclosed. The method includes forming a quaternary heterovalent compound semiconductor alloy epilayer, determining a doping characteristic of the epilayer, and forming a secondary layer on the epilayer to create a semiconductor junction, the secondary layer being doped in response to the determined doping characteristic of the epilayer. Solar cell and light emitting diode designs are also disclosed.

### CROSS REFERENCE TO RELATED APPLICATIONS

This application claims priority under 35 U.S.C. §119(e) to U.S. Provisional Patent Application Ser. No. 61/238,310, filed on Aug. 31, 2009, and entitled “Method of Fabricating PN Junction,” the entire disclosure of which is expressly incorporated herein by reference.

### TECHNICAL FIELD

The present disclosure generally relates to the field of compound semiconductor devices. More specifically, the present disclosure relates to a method of fabricating a semiconductor junction using a quaternary heterovalent compound semiconductor alloy.

### BACKGROUND

A semiconductor junction may be formed through a variety of processes. As used herein, a “semiconductor junction” refers to an interface formed between a p-type semiconductor and an n-type semiconductor (a “PN junction”) or between a p-type semiconductor, an intrinsic semiconductor, and an n-type semiconductor (a “PIN junction”). A semiconductor is classified as “p-type” when elemental atoms (i.e., acceptor dopants) with fewer free electrons than the native semiconductor atoms are infused into the semiconductor and displace a given number of native atoms. This infusion and displacement creates a deficit of electrons; correspondingly, an excess supply of holes (i.e., positively charged particles) is created in the semiconductor. Alternatively, a semiconductor is classified as “n-type” when elemental atoms (i.e., donor dopants) with more free electrons than the native semiconductor atoms are infused into the semiconductor and displace a given number of native atoms. Correspondingly, this infusion and displacement creates an excess supply of electrons. For both types of doping, charge neutrality is conserved due to the ionization of the acceptor or donor sites, respectively. A semiconductor may also be classified as “intrinsic” when only negligible doping (of either p-type or n-type) is present. In compound semiconductors, the concept of doping becomes slightly more complicated, as some elements become “amphoteric” in nature. An element classified as amphoteric may act as either an acceptor or as a donor, depending on where it settles in the semiconductor lattice. The amphotericity of an element is accentuated as compounds move from binary in nature to ternary and quaternary in nature.

An example of one such quaternary compound is the alloy ZnSe—GaAs, composed of zinc selenide (“ZnSe”) and gallium arsenide (“GaAs”). The exact doping mechanisms of ZnSe—GaAs have not been fully understood in the art, as zinc (“Zn”) and selenium (“Se”) are both capable of doping GaAs (p-type and n-type, respectively), while gallium (“Ga”) and arsenic (“As”) are both amphoteric dopants in ZnSe. Given these doping mechanisms, when a ZnSe—GaAs crystalline alloy is grown (either in bulk form or epitaxially), it is difficult to control or predict doping, either p-type or n-type. Solid solutions of ZnSe—GaAs have been previously found to be p-type at up to 60 mole percent of ZnSe, despite the lack of any extrinsic dopants. At higher ZnSe mole percentages, the doping was indeterminable due to high electrical resistance. Due to these facts, creating a homojunction of n-type ZnSe—GaAs to p-type ZnSe—GaAs is particularly challenging.

One application of compound semiconductors is the fabrication of high band gap solar cells. In order to achieve solar conversion efficiencies over 50%, multijunction solar cell devices containing at least four semiconductor junctions (or sub-cells) are typically needed. However, within each multijunction device design, a tradeoff is created depending on the choice of each sub-cell's band gap. For devices containing four to five semiconductor junctions, a top cell with an optimum band gap of between 2.3 eV and 2.5 eV is required. Further, a recent investigation targeting 50% efficiency with six semiconductor junctions found an optimum band gap of 2.4 eV for designs utilizing currently available lower band gap cells. Currently, no proven material systems realize high efficiency cells that utilize the optimum band gap of about 2.4 eV. More importantly, no currently investigated gap materials with a band gap of about 2.4 eV are lattice matched to either silicon (“Si”) or GaAs. This issue is relevant because high efficiency solar cells should be defect-free and, preferably, grown on lattice-matched substrates.

Theoretically, an indium-gallium nitride (“InGaN”) alloy system could achieve the desired band gap. However, InGaN alloy systems are not lattice-matched to commercially available defect-free substrates. In addition, the formation of defects in these alloy systems prevents the realization of high performance cells because of the crystal structure strain and phase separation between indium nitride (“InN”) and gallium nitride (“GaN”). From a commercial perspective, gallium indium phosphide (“GaInP”) has been the high band gap material of choice that can be lattice-matched to GaAs. However, the band gap of GaInP is only 1.89 eV—a significantly lower value than the optimal band gap of 2.4 eV. While pure ZnSe (a II-VI compound semiconductor) can be n-doped or p-doped, its band gap of 2.67 eV is higher than those of the ZnSe(x)GaAs(1-x) alloys and will absorb only a minimal amount of light from the solar spectrum.

Another application of compound semiconductors is the fabrication of light emitting diodes (“LEDs”) having a true green color (i.e., a wavelength range of about 555 nm to about 560 nm). Previous LED systems have incorporated indium-rich compositions such as InGaN. While InGaN alloy systems are capable of producing high brightness blue-green LEDs (with a wavelength of about 532 nm), they are unable to reach true green due to phase separation of InN in indium-rich compositions. Other previous systems have incorporated gallium phosphide-based compositions such as gallium-phosphide (“GaP”) or aluminum gallium indium phosphide (“AlGaInP”) to produce a yellow-green light emitting diode (with a wavelength of about 567 nm). None of these previous systems have been capable of generating high energy photons in the range of about 2.0 to 2.3 eV to achieve a true green color in the wavelength range of about 555-560 nm.

These and other background considerations are described in: A. Barnett et al., “50% Efficient Solar Cell Architectures and Designs,” Conference Record of the 2006 IEEE 4th World Conference on Photovoltaic Energy Conversion, 2560-64 (2006); C. Brünig et al., “Chemical Vapor Transport of Solid Solutions. Formation of Solid Solutions and Chemical Vapor Transport in the System GaAs/ZnSe,” 632 J. Inorganic & Gen. Chemistry 1067-72 (2006); A. De Vos, “Detailed Balance Limit of the Efficiency of Tandem Solar Cells,” 13 J. Physics D: Applied Physics 839-846 (1980); M. Kaji et al., “Liquid-Phase Epitaxy of GaAs—ZnSe—Ga2Se3 Alloy Crystals on a ZnSe Substrate,” 178 J. Crystal Growth 242-45 (1997); G. F. Neumark, “Blue-Green Diode Lasers,” 47 Physics Today 26-32 (1994); A. Saidov et al., “Liquid Phase Epitaxy of (GaAs)1-x(ZnSe)x Solid Solution Layers from a Lead-Based Solution Melt,” 27 Technical Physics Letters 973-74 (2001); L. G. Wang et al., “Dilute Nonisovalent (II-VI)-(III-V) Semiconductor Alloys: Monodoping, Codoping, and Cluster Doping in ZnSe—GaAs,” 68 Physical Rev. B (Condensed Matter & Materials Physics) 125211-18 (2003); W. M. Yim, “Solid Solutions in Pseudobinary (III-V)-(II-VI) Systems and Their Optical Energy Gaps,” 40 J. Applied Physics 2617-23 (1969); W. M. Yim et al., “Vapor Growth of (II-V)-(III-IV) Quarternary Alloys and Their Properties,” 31 RCA Review 662-79 (1970); and T. Zdanowicz et al., “Theoretical Analysis of the Optimum Energy Band Gap of Semiconductors for Fabrication of Solar Cells for Applications in Higher Latitude Locations,” 87 Solar Energy Materials & Solar Cells 757-69 (2005). The entire disclosures of each of the above listed references are expressly incorporated by reference herein. This listing is not intended as a representation that a complete search of all relevant prior art has been conducted or that no better reference than those listed above exist; nor should any such representation be inferred.

### SUMMARY OF THE INVENTION

The present invention comprises one or more of the features recited in the appended claims and/or the following features which, alone or in any combination, may comprise patentable subject matter:

According to one aspect, a method includes forming a quaternary heterovalent compound semiconductor alloy epilayer, determining a doping characteristic of the epilayer, and forming a secondary layer on the epilayer to create a semiconductor junction, where the secondary layer is doped in response to the determined doping characteristic of the epilayer. In some embodiments, determining the doping characteristic of the epilayer may include determining whether the epilayer is p-type, n-type, or intrinsic. In such embodiments, determining whether the epilayer is p-type, n-type, or intrinsic may include measuring the conductivity of the epilayer.

In some embodiments, forming the secondary layer on the epilayer to create the semiconductor junction may include creating a PN junction between the epilayer and the secondary layer. In other embodiments, forming the quaternary heterovalent compound semiconductor alloy epilayer may include epitaxially growing the epilayer on a base layer. Forming the secondary layer on the epilayer to create the semiconductor junction in such embodiments may include creating a PIN junction between the base layer, the epilayer, and the secondary layer.

In other embodiments, forming a quaternary heterovalent compound semiconductor alloy epilayer may include epitaxially growing a ZnSe(x)GaAs(1-x) alloy epilayer, where 0<x<1. Forming the secondary layer on the epilayer may include epitaxially growing an n-type ZnSe secondary layer when the doping characteristic of the epilayer is determined to be p-type. Alternatively, forming the secondary layer on the epilayer comprises epitaxially growing a p-type ZnSe secondary layer when the doping characteristic of the epilayer is determined to be n-type. In still other embodiments, forming the quaternary heterovalent compound semiconductor alloy epilayer may include epitaxially growing a ZnSe(x)GaAs(1-x) alloy epilayer, where 0<x<1, on a ZnSe base layer. In such embodiments, forming the secondary layer on the epilayer may include epitaxially growing a ZnSe secondary layer when the doping characteristic of the epilayer is determined to be intrinsic, where the ZnSe secondary layer and the ZnSe base layer have opposite doping types.

According to another aspect, a solar cell has at least one semiconductor junction that includes a quaternary heterovalent compound semiconductor alloy epilayer having a first doping type and a secondary layer epitaxially grown on the epilayer and having a second doping type, where the second doping type is different than the first doping type. In some embodiments, the quaternary heterovalent compound semiconductor alloy epilayer may be ZnSe(x)GaAs(1-x), where 0<x<1, and the secondary layer may be ZnSe. In other embodiments, the at least one semiconductor junction may further include a ZnSe base layer having a third doping type, where the third doping type is different than the first and second doping types. The epilayer may have a band gap in the range of about 2.3 eV to about 2.5 eV.

According to yet another aspect, a light emitting diode has at least one semiconductor junction that includes a quaternary heterovalent compound semiconductor alloy epilayer having a first doping type and a secondary layer epitaxially grown on the epilayer and having a second doping type, where the second doping type is different than the first doping type. In some embodiments, the quaternary heterovalent compound semiconductor alloy epilayer may be ZnSe(x)GaAs(1-x), where 0<x<1, and the secondary layer may be ZnSe. In other embodiments, the at least one semiconductor junction may further include a ZnSe base layer having a third doping type, where the third doping type is different than the first and second doping types. The epilayer may have a band gap in the range of about 2.0 eV to about 2.3 eV. In some embodiments, the light emitting diode may be configured to emit a wavelength in the range of about 555 nanometers to about 560 nanometers.

Additional features, which alone or in combination with any other feature(s), including those listed above and those listed in the claims, may comprise patentable subject matter and will become apparent to those skilled in the art upon consideration of the following detailed description of illustrative embodiments exemplifying the best mode of carrying out the invention as presently perceived.

### BRIEF DESCRIPTION OF THE DRAWINGS

The detailed description particularly refers to the accompanying figures in which:

FIG. 1 is a simplified flowchart illustrating one embodiment of a method of fabricating a semiconductor junction according to the present disclosure;

FIG. 2 is a plot showing the optical band gaps for varying compositions of ZnSe(x)GaAs(x-1) (reprinted from W. M. Yim, “Solid Solutions in Pseudobinary (III-V)-(II-VI) Systems and Their Optical Energy Gaps,” cited above);

FIG. 3 illustrates a cross section of one embodiment of an n—ZnSe/p—ZnSe(x)GaAs(x-1) PN junction fabricated according to the process FIG. 1;

FIG. 4 illustrates a cross section of one embodiment of a p—ZnSe/n—ZnSe(x)GaAs(x-1) PN junction fabricated according to the process FIG. 1;

FIG. 5 illustrates a cross section of one embodiment of an n—ZnSe/intrinsic—ZnSe(x)GaAs(x-1)/p—ZnSe PIN junction fabricated according to the process FIG. 1;

FIG. 6 illustrates a cross section of one embodiment of a multijunction solar cell design utilizing the PN junction of FIG. 3; and

FIG. 7 illustrates a cross section of one embodiment of a light emitting diode design utilizing the PIN junction of FIG. 5.

### DETAILED DESCRIPTION OF THE DRAWINGS

While the concepts of the present disclosure are susceptible to various modifications and alternative forms, specific exemplary embodiments thereof have been shown by way of example in the drawings and will herein be described in detail. It should be understood, however, that there is no intent to limit the concepts of the present disclosure to the particular forms disclosed, but, on the contrary, the intention is to cover all modifications, equivalents, and alternatives falling within the spirit and scope of the invention as defined by the appended claims.

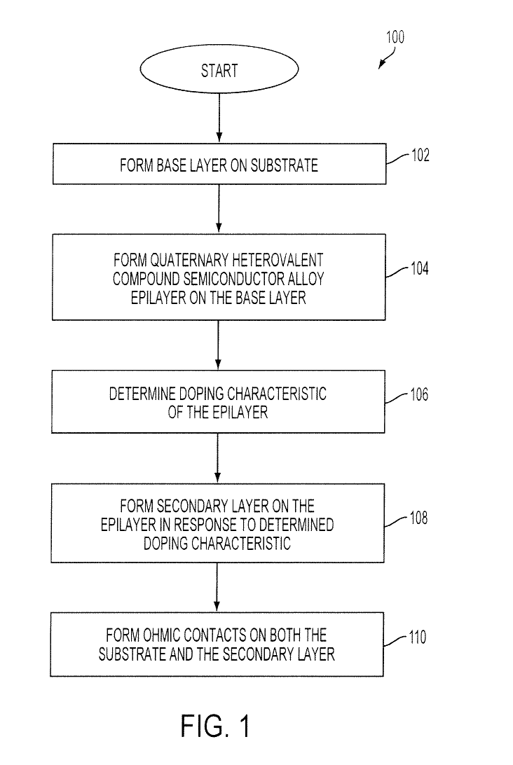

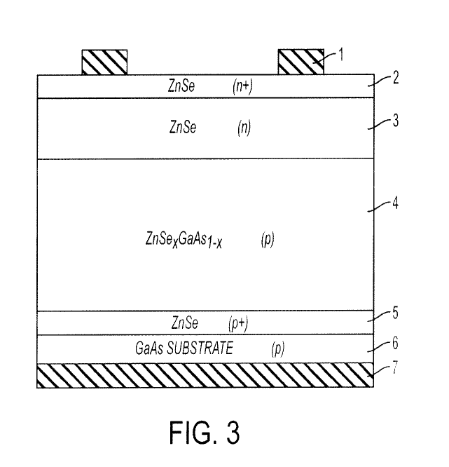

Referring now to FIG. 1, an illustrative embodiment of a process 100 for fabricating a semiconductor junction is represented as a simplified flowchart. The process 100 may be used to form the semiconductor junctions shown in FIGS. 3-5, among other structures. As shown in FIG. 1, the process 100 begins with step 102 in which a base layer 5, 12, 19 is formed on a substrate 6, 13, 20. One illustrative method for epitaxially depositing the base layer 5, 12, 19 on the substrate 6, 13, 20 during step 102 is open tube vapor phase epitaxy (“VPE”), which may employ an apparatus similar to that taught in W. M. Yim et al. (cited above).

In the structures of FIGS. 3-5, the substrate 6, 13, 20 is illustratively embodied as a GaAs substrate of <100> orientation and the base layer 5, 12, 19 is illustratively embodied as a layer of pure ZnSe that is epitaxially grown on the GaAs substrate. The use of the pure ZnSe base layer 5, 12, 19 on the GaAs substrate 6, 13, 20 allows for a closer match of lattice constant and thermal expansion coefficients with a ZnSe(x)GaAs(x-1) alloy epilayer 4, 11, 18 to be subsequently grown on the structures. One set of exemplary conditions for growing the ZnSe base layer 5, 12, 19 include: a zinc source at about 530° C.; a substrate at about 890° C.; a flow rate of about 200 cc/min of H₂ over the zinc source; a reaction zone at about 925° C. to about 1000° C.; and flow rates to the reaction zone of about 2.5 cc/min and about 700 cc/min for H₂Se and H₂, respectively. Under these conditions, the growth rate of ZnSe during the step 102 is about 36 μm/hr. It will be appreciated by those of skill in the art that, in other embodiments, other semiconductor materials may be used for the substrate 6, 13, 20 and for the base layer 5, 12, 19 and that other methods of forming the base layer 5, 12, 19 may be employed.

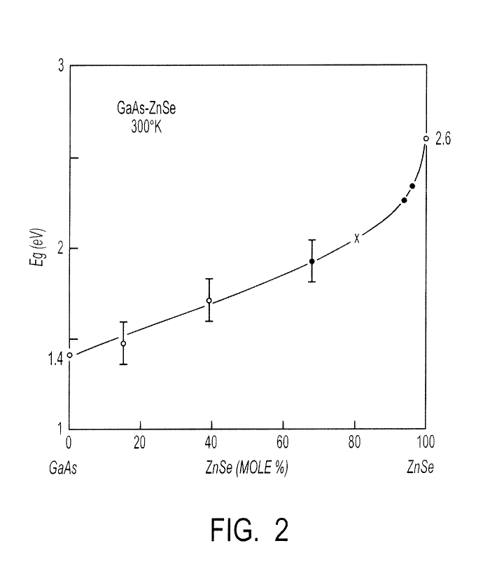

After the step 102, the process 100 proceeds to step 104 in which a quaternary heterovalent compound semiconductor alloy epilayer 4, 11, 18 is formed on top of the base layer 5, 12, 19. In the structures of FIGS. 3-5, the epilayer 4, 11, 18 is illustratively embodied as a ZnSe(x)GaAs(x-1) alloy epilayer that is epitaxially grown on top of the ZnSe base layer. In the formula ZnSe(x)GaAs(x-1), the value of “x” is greater than 0 but less than 1. FIG. 2 demonstrates the optical band gaps that may be achieved for varying ZnSe(x)GaAs(x-1) alloy compositions. By way of example, to achieve a band gap of about 2.4 eV, the following growth conditions may be used with open-tube VPE: a zinc source at about 530° C.; a gallium source at about 825° C.; a substrate at about 890° C.; a flow rate of about 200 cc/min of H₂ over the zinc source; flow rates of about 290 cc/min and about 1 cc/min for H₂ and HCl, respectively, over the gallium source; a reaction zone at about 925° C. to about 1000° C.; and flow rates to the reaction zone of about 2.5 cc/min, about 9 cc/min, and about 350 cc/min for H₂Se, AsH₃, and H₂, respectively. Under these conditions, the growth rate of ZnSe(x)GaAs(x-1) during the step 104 is about 18 μm/hr. Those of skill in the art will be able to appropriately vary the conditions used to form the ZnSe(x)GaAs(x-1) alloy epilayer 4, 11, 18, using the relationship shown in FIG. 2, to achieve any desired band gap between 1.4 eV and 2.67 eV. It is also contemplated that other quaternary heterovalent compound semiconductor alloys may be used to form the epilayer 4, 11, 18. Furthermore, the epilayer 4, 11, 18 may be formed using any suitable epitaxial growth technique, including, but not limited to, the VPE technique described above, molecular beam epitaxy (“MBE”), metal-organic chemical vapor deposition (“MOCVD”), liquid phase epitaxy (“LPE”), solid phase epitaxy (“SPE”), and the like.

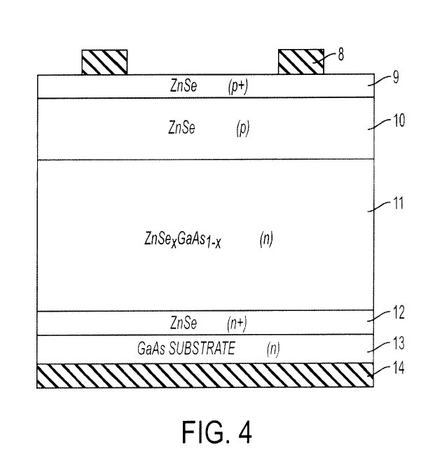

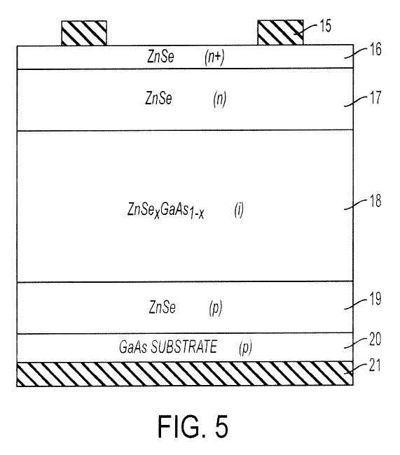

After the step 104, the process 100 proceeds to step 106 in which a doping characteristic of the quaternary heterovalent compound semiconductor alloy epilayer 4, 11, 18 is determined. In some embodiments, the conductivity of the epilayer may be measured for a determination of n-type doping, p-type doping, or intrinsic doping. In other words, irrespective of the exact technique used to grow a ZnSe—GaAs crystal alloy, the ZnSe—GaAs alloy epilayer 4, 11, 18 resulting from that technique may be classified in one of three categories (i.e., p-type, n-type, or intrinsic). In the illustrative embodiment of FIG. 1, once the growth of the ZnSe(x)GaAs(1-x) alloy epilayer 4, 11, 18 is completed in step 104 and the doping of the epilayer is determined in step 106, the appropriate embodiment of the semiconductor junction may be chosen accordingly. This determination of the doping characteristic of the epilayer 4, 11, 18 thus informs the action taken in step 108 of the process 100 (as described below)—namely, whether a PN junction should be formed (as illustratively shown in FIGS. 3 and 4) or a PIN junction should be formed (as illustratively shown in FIG. 5).

If the ZnSe(x)GaAs(1-x) alloy epilayer is determined to be p-type in step 106, a PN junction can be created, as shown in FIG. 3. Starting with a p-type GaAs substrate 6, a thin base layer 5 (illustratively about 200 nm to about 400 nm) of p+ZnSe is deposited during step 102. As described above, the p+ZnSe base layer 5 may be deposited using VPE, MBE, MOCVD, LPE, SPE, or any other suitable epitaxial growth technique. This p+ZnSe base layer 5 creates ohmic characteristics between the epilayer 4 and a metal contact 7 (further described below). Over the p+ZnSe base layer 5, the p-type ZnSe(x)GaAs(1-x) alloy epilayer 4 is grown in step 104 using either VPE, MBE, MOCVD, LPE, SPE, or another epitaxial growth technique. In this illustrative embodiment, the thickness of the epilayer 4 is around 500 nm, which should be sufficient to collect up to 99% of all photons of energies above the band gap of the alloy. As described with reference to FIG. 2, the band gap of the alloy ranges from about 1.4 eV to about 2.7 eV, depending on the composition of the chosen ZnSe(x)GaAs(1-x) alloy.

During step 108 of the process 100 (with regard to the illustrative embodiment of FIG. 3), an alternatively doped n-type ZnSe secondary layer 3 is grown over the p-type epilayer 4 using either VPE, MBE, MOCVD, LPE, SPE, or another epitaxial growth technique. In other words, the doping of the secondary layer 3 (i.e., n-type) is chosen in response to the doping characteristic of the epilayer 4 (i.e., p-type) determined in step 106. The p-type epilayer 4 and n-type ZnSe secondary layer 3 thus form a PN junction. After step 108, the process 100 proceeds to step 110 in which ohmic contacts are provided for the PN junction. First, a layer of n+ZnSe 2 is grown on top of the n-type ZnSe secondary layer 3 (the n+ZnSe layer 2 is needed for the ohmic quality of the metal contacts 1). Next, a grid of first metal contacts 1 is deposited on the n+ZnSe layer 2. Finally, a second metal ohmic contact 7 is deposited on substantially the entire back surface of the GaAs substrate 6.

If the ZnSe(x)GaAs(1-x) alloy epilayer is determined to be n-type in step 106, a PN junction can be created, as shown in FIG. 4. Starting with a n-type GaAs substrate 13, a thin base layer 12 (illustratively about 200 nm to about 400 nm) of n+ZnSe is deposited during step 102. As described above, the n+ZnSe base layer 12 may be deposited using VPE, MBE, MOCVD, LPE, SPE, or any other suitable epitaxial growth technique. This n+ZnSe base layer 12 creates ohmic characteristics between the epilayer 11 and a metal contact 14 (further described below). Over the n+ZnSe base layer 12, the n-type ZnSe(x)GaAs(1-x) alloy epilayer 11 is grown in step 104 using either VPE, MBE, MOCVD, LPE, SPE, or another epitaxial growth technique. In this illustrative embodiment, the thickness of the epilayer 11 is around 500 nm, which should be sufficient to collect up to 99% of all photons of energies above the band gap of the alloy. As described with reference to FIG. 2, the band gap of the alloy ranges from about 1.4 eV to about 2.7 eV, depending on the composition of the chosen ZnSe(x)GaAs(1-x) alloy.

During step 108 of the process 100 (with regard to the illustrative embodiment of FIG. 4), an alternatively doped p-type ZnSe secondary layer 10 is grown over the n-type epilayer 11 using either VPE, MBE, MOCVD, LPE, SPE, or another epitaxial growth technique. In other words, the doping of the secondary layer 10 (i.e., p-type) is chosen in response to the doping characteristic of the epilayer 11 (i.e., n-type) determined in step 106. The n-type epilayer 11 and p-type ZnSe secondary layer 10 thus form a PN junction. After step 108, the process 100 proceeds to step 110 in which ohmic contacts are provided for the PN junction. First, a layer of p+ZnSe 9 is grown on top of the p-type ZnSe secondary layer 10 (the p+ZnSe layer 9 is needed for the ohmic quality of the metal contacts 8). Next, a grid of first metal contacts 8 is deposited on the p+ZnSe layer 9. Finally, a second metal ohmic contact 12 is deposited on substantially the entire back surface of the GaAs substrate 13.

If the ZnSe(x)GaAs(1-x) alloy epilayer is determined to be intrinsic in step 106, a PIN junction can be created, as shown in FIG. 5. Starting with a p-type GaAs substrate 20, a base layer 19 of p-type ZnSe is deposited during step 102. As described above, the p-type ZnSe base layer 19 may be deposited using VPE, MBE, MOCVD, LPE, SPE, or any other suitable epitaxial growth technique. Over the p-type ZnSe base layer 19, the intrinsic ZnSe(x)GaAs(1-x) alloy epilayer 18 is grown in step 104 using either VPE, MBE, MOCVD, LPE, SPE, or another epitaxial growth technique. In this illustrative embodiment, the thickness of the epilayer 18 is around 500 nm, which should be sufficient to collect up to 99% of all photons of energies above the band gap of the alloy. As described with reference to FIG. 2, the band gap of the alloy ranges from about 1.4 eV to about 2.7 eV, depending on the composition of the chosen ZnSe(x)GaAs(1-x) alloy.

During step 108 of the process 100 (with regard to the illustrative embodiment of FIG. 5), an alternatively doped n-type ZnSe secondary layer 17 is grown over the intrinsic epilayer 18 using either VPE, MBE, MOCVD, LPE, SPE, or another epitaxial growth technique. In other words, the doping of the secondary layer 17 (i.e., n-type) is chosen in response to the doping characteristic of the epilayer 18 (i.e., intrinsic) determined in step 106, as well as the doping of the ZnSe base layer 19 (i.e., p-type). The p-type ZnSe base layer 19, the intrinsic epilayer 18, and the n-type ZnSe secondary layer 17 thus form a PIN junction. It will be appreciated that, in other embodiments, the ZnSe base layer 19 may be n-type and the ZnSe secondary layer 17 may be p-type. After step 108, the process 100 proceeds to step 110 in which ohmic contacts are provided for the PIN junction. First, a layer of n+ZnSe 16 is grown on top of the n-type ZnSe secondary layer 17 (the n+ZnSe layer 16 is needed for the ohmic quality of the metal contacts 15). Next, a grid of first metal contacts 15 is deposited on the n+ZnSe layer 16. Finally, a second metal ohmic contact 21 is deposited on substantially the entire back surface of the GaAs substrate 20.

Semiconductor junctions fabricated according to the process 100 (such as the illustrative embodiments of FIGS. 3-5) may be used in many applications. When utilized in solar cell applications, these semiconductor junctions allow for the absorbance of solar photons between about 1.4 eV to about 2.7 eV. In such solar cells, the open circuit voltage of the PN junction or PIN junction will be determined by the band gap of the ZnSe(x)GaAs(1-x) alloy epilayer 4, 11, 18 and not by the pure ZnSe layers 3, 10, 17, 19 (which have a higher band gap). Accordingly, kinetic energy loss of the photo-excited carriers may be minimized by using multiple sub-cells in a multijunction solar cell design. Each sub-cell may decrease in band gap from the top to the bottom of the stack.

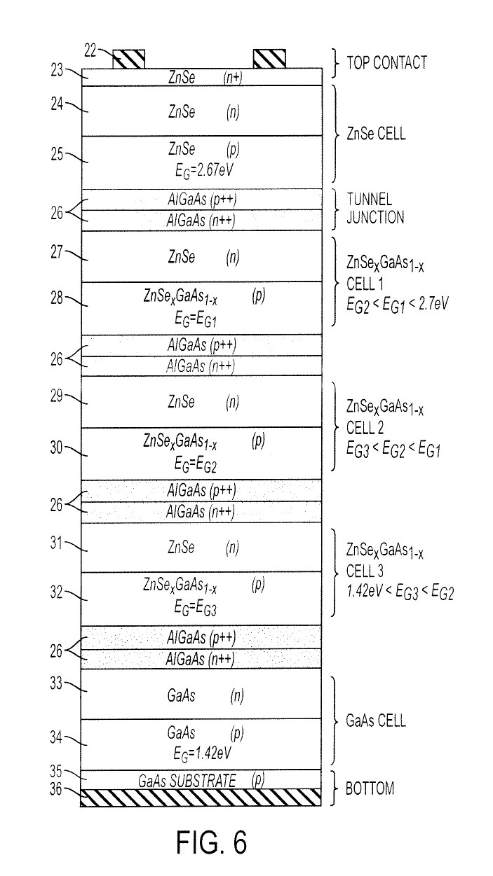

One illustrative embodiment of such a multijunction solar cell design is shown in FIG. 6. Each of the three ZnSeGaAs sub-cells of FIG. 6 includes a ZnSe(x)GaAs(1-x) alloy epilayer 28, 30, 32 and a ZnSe secondary layer 27, 29, 31. It will be appreciated that, while the embodiment of FIG. 6 shows all of the ZnSe/ZnSeGaAs sub-cells having the p-type ZnSeGaAs configuration (of FIG. 3), another embodiment could substitute the n-type or intrinsic configurations (of FIGS. 4 and 5) in a similar fashion. If series electrical connections are needed between the sub-cells, thin aluminum gallium arsenide (“AlGaAs”) ohmic tunnel junctions 26 may be used to connect the series. This design allows current to flow easily from one sub-cell to the next in a series configuration, as there are only two ohmic contacts 22, 23 (top) and 35, 36 (bottom).

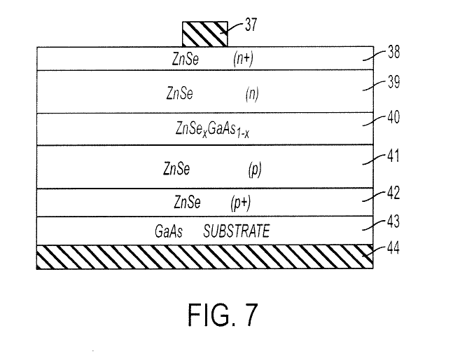

Another possible application of a semiconductor junction formed according to the process 100 is a light emitting diode (LED). By using a ZnSeGaAs alloy as the active region, LEDs with emission from the infrared to deep blue may be produced by simply varying the composition of the alloy. One illustrative embodiment has the structure of a quantum well LED, as shown in FIG. 7 (not to scale). In this embodiment, the thickness of the ZnSe(x)GaAs(1-x) epilayer 40 is very thin (illustratively about 25-100 angstroms) in order to achieve proper quantum confinement of the electrons and holes. As shown in FIG. 7, the epilayer 40 is confined by ZnSe blocking layers 39, 41 of opposite doping types. In the illustrative embodiment, the ZnSe(x)GaAs(1-x) alloy epilayer 40 is intrinsic, as dopants can raise the electron concentration in the well to the point of increasing non-radiative Auger recombination. Proper carrier separation is enabled through the n-type ZnSe layer 39 and the p-type ZnSe layer 41. Layers 37, 44 are metal ohmic contacts, while ZnSe layers 38, 42 (having n+ and p+ doping, respectively) promote proper ohmic contact formation. Layer 43 is the GaAs substrate used to grow the various layers.

This LED design, illustrated in FIG. 7, allows the achievement of a true-green LED having a wavelength of about 555 nm to about 560 nm. This true-green color is made possible because the ZnSe(x)GaAs(1-x) alloy epilayer 40 may be configured to have a band gap of about 1.5 eV to about 2.3 eV and, specifically, a band gap that is tunable in the range of about 2.0 eV to about 2.3 eV, so as to achieve the true-green LED. In an alternative embodiment for the LED structure, the epilayer 40 may be composed of multiple quantum wells of ZnSeGaAs, with intrinsic ZnSe cladding layers 39, 41 in between the quantum wells of ZnSeGaAs. This configuration would aid in greater photon emission.

While the disclosure has been illustrated and described in detail in the drawings and foregoing description, such an illustration and description is to be considered as exemplary and not restrictive in character, it being understood that only illustrative embodiments have been shown and described and that all changes and modifications that come within the spirit of the disclosure are desired to be protected. For example, while the illustrative embodiment of the process 100 describes (in detail) the use of VPE to form the ZnSe(x)GaAs(1-x) alloy epilayer, other embodiments of the process 100 may employ other epitaxial growth techniques for step 104. This alternative epitaxial growth techniques may require further modifications to the process 100.

For instance, in an alternative embodiment using LPE (rather than VPE), a ZnSe substrate may be used in the process 100 to avoid several issues faced by GaAs substrates. First, ZnSe has a higher level of solubility at a given temperature than GaAs. Second, in order to make alloys that are ZnSe—rich, the amount of GaAs in the growth melt may be limited. Using GaAs substrates in ZnSe—rich melts would likely result in etchback of the GaAs substrate, negatively affecting the composition of the melt. The composition of the melt used in step 104 will vary based on the desired composition of the ZnSe(x)GaAs(1-x) alloy epilayer. For a high band gap solar cell (e.g., where a band gap of 2.3 eV is desired), 98 mol % ZnSe pieces with 2 mol % GaAs pieces may be loaded in a tin-based solution. After ensuring the melt is supersaturated at a temperature of 900° C., the equilibrium cooling technique may be used down to a temperature of 875° C., resulting in a film thickness of about 2 μm. After growth of the ZnSe(x)GaAs(1-x) alloy epilayer, the conductivity of the film can be measured during step 106 using the 4-point probe method or Hall measurements. After the doping characteristic is determined (i.e., p-type, n-type, or intrinsic), a multi-layer process may be implemented, as described above. It is also contemplated that the methods of the present disclosure may be applied to the fabrication of any type of compound semiconductor device (in addition to solar cells and LEDs).

Furthermore, there are a plurality of advantages of the present disclosure arising from the various features of the methods and systems described herein. It will be noted that alternative embodiments of the methods and systems of the present disclosure may not include all of the features described yet still benefit from at least some of the advantages of such features. Those of ordinary skill in the art may readily devise their own implementations of the methods and systems that incorporate one or more of the features of the present invention and fall within the spirit and scope of the present disclosure as defined by the appended claims.

1. A method comprising:
forming a quaternary heterovalent compound semiconductor alloy epilayer;
determining a doping characteristic of the epilayer; and
forming a secondary layer on the epilayer to create a semiconductor junction, the secondary layer being doped in response to the determined doping characteristic of the epilayer.

2. The method of claim 1, wherein determining the doping characteristic of the epilayer comprises determining whether the epilayer is p-type, n-type, or intrinsic.

3. The method of claim 2, wherein determining whether the epilayer is p-type, n-type, or intrinsic comprises measuring the conductivity of the epilayer.

4. The method of claim 1, wherein forming the secondary layer on the epilayer to create the semiconductor junction comprises creating a PN junction between the epilayer and the secondary layer.

5. The method of claim 1, wherein forming the quaternary heterovalent compound semiconductor alloy epilayer comprises epitaxially growing the epilayer on a base layer.

6. The method of claim 5, wherein forming the secondary layer on the epilayer to create the semiconductor junction comprises creating a PIN junction between the base layer, the epilayer, and the secondary layer.

7. The method of claim 1, wherein forming a quaternary heterovalent compound semiconductor alloy epilayer comprises epitaxially growing a ZnSe(x)GaAs(1-x) alloy epilayer, where 0<x<1.

8. The method of claim 7, wherein forming the secondary layer on the epilayer comprises epitaxially growing an n-type ZnSe secondary layer when the doping characteristic of the epilayer is determined to be p-type.

9. The method of claim 7, wherein forming the secondary layer on the epilayer comprises epitaxially growing a p-type ZnSe secondary layer when the doping characteristic of the epilayer is determined to be n-type.

10. The method of claim 1, wherein forming the quaternary heterovalent compound semiconductor alloy epilayer comprises epitaxially growing a ZnSe(x)GaAs(1-x) alloy epilayer, where 0<x<1, on a ZnSe base layer.

11. The method of claim 10, wherein forming the secondary layer on the epilayer comprises epitaxially growing a ZnSe secondary layer when the doping characteristic of the epilayer is determined to be intrinsic, the ZnSe secondary layer and the ZnSe base layer having opposite doping types.

12. Apparatus comprising:
a solar cell having at least one semiconductor junction including:
a quaternary heterovalent compound semiconductor alloy epilayer having a first doping type; and
a secondary layer epitaxially grown on the epilayer and having a second doping type, the second doping type being different than the first doping type.

13. The apparatus of claim 12, wherein:
the quaternary heterovalent compound semiconductor alloy epilayer comprises ZnSe(x)GaAs(1-x), where 0<x<1; and
the secondary layer comprises ZnSe.

14. The apparatus of claim 13, wherein the at least one semiconductor junction further includes a ZnSe base layer having a third doping type, the third doping type being different than the first and second doping types.

15. The apparatus of claim 12, wherein the epilayer has a band gap in the range of about 2.3 eV to about 2.5 eV.

16. Apparatus comprising:
a light emitting diode having at least one semiconductor junction including:
a quaternary heterovalent compound semiconductor alloy epilayer having a first doping type; and
a secondary layer epitaxially grown on the epilayer and having a second doping type, the second doping type being different than the first doping type.

17. The apparatus of claim 16, wherein:
the quaternary heterovalent compound semiconductor alloy epilayer comprises ZnSe(x)GaAs(1-x), where 0<x<1; and
the secondary layer comprises ZnSe.

18. The apparatus of claim 17, wherein the at least one semiconductor junction further includes a ZnSe base layer having a third doping type, the third doping type being different than the first and second doping types.

19. The apparatus of claim 16, wherein the epilayer has a band gap in the range of about 2.0 eV to about 2.3 eV.

20. The apparatus of claim 16, wherein the light emitting diode is configured to emit a wavelength in the range of about 555 nanometers to about 560 nanometers.
